(19) United States
(12) Patent Application Publication
(10) Pub. No.: US 2025/0176341 A1
(43) Pub. Date: May 29, 2025

(54) METHOD FOR PRODUCING A PLURALITY OF OPTOELECTRONIC SEMICONDUCTOR CHIPS, AND OPTOELECTRONIC SEMICONDUCTOR CHIP

(71) Applicant: AMS-OSRAM INTERNATIONAL GMBH, Regensburg (DE)

(72) Inventor: Reiner Windisch, Pettendorf (DE)

(21) Appl. No.: 18/730,675

(22) PCT Filed: Dec. 23, 2022
(86) PCT No.: PCT/EP2022/087759

§ 371 Date: Jul. 19, 2024

(30) Foreign Application Priority Data
Jan. 24, 2022 (DE) 102022101575.0

(51) Int. Cl. H10H 20/80; H10H 20/01; H10H 20/813; H10H 20/825; H10H 20/857

(52) U.S. Cl. CPC H10H 20/872; H10H 20/01335; H10H 20/019; H10H 20/0363; H10H 20/0364; H10H 20/8132; H10H 20/825; H10H 20/857; H10H 20/882

(57) ABSTRACT

In an embodiment a method for manufacturing a plurality of optoelectronic semiconductor chips includes providing a growth surface with a plurality of LED areas, which are separated from each other by reflector areas, epitaxial growing epitaxial semiconductor columns on the growth surface, epitaxial coalescing the epitaxial semiconductor columns so that a closed semiconductor surface is formed, epitaxial growing an active semiconductor layer on or over the closed semiconductor surface, wherein the active semiconductor layer is configured to generate electromagnetic radiation and removing the active semiconductor layer over the reflector areas such that a plurality of active semiconductor areas is generated over the LED areas.

### CROSS-REFERENCE TO RELATED APPLICATIONS

This patent application is a national phase filing under section 371 of PCT/EP2022/087759, filed Dec. 23, 2022, which claims the priority of German patent application 102022101575.0, filed Jan. 24, 2022, each of which is incorporated herein by reference in its entirety.

### TECHNICAL FIELD

A method of manufacturing a plurality of optoelectronic semiconductor chips and an optoelectronic semiconductor chip are provided.

### SUMMARY

Embodiments provide an improved optoelectronic semiconductor chip, which in particular has a comparatively small edge length. Further embodiments provide a simplified method for manufacturing an optoelectronic semiconductor chip.

According to an embodiment of the method for manufacturing a plurality of optoelectronic semiconductor chips, a growth surface with a plurality of LED areas separated from each other by reflector areas is provided. In particular, the growth surface is configured for the epitaxial growth of a III/V compound semiconductor material, particularly preferably for the epitaxial growth of a nitride compound semiconductor material. Nitride compound semiconductor materials are compound semiconductor materials that contain nitrogen, such as the materials from the system InₓAl_{y}Ga_{1-x-y}N with 0≤x≤1, 0≤y≤1 and x+y≤1.

For example, the growth surface is formed by a main surface of a growth substrate. Furthermore, it is also possible that the growth surface is formed by a semiconductor growth layer grown epitaxially on the growth substrate. For example, the epitaxially grown semiconductor growth layer comprises an n-doped nitride compound semiconductor material or consists of an n-doped nitride compound semiconductor material.

In particular, the growth surface is part of a wafer. In other words, the present method preferably takes place in a wafer composite, wherein a plurality of optoelectronic semiconductor chips is produced simultaneously in parallel. As a rule, the optoelectronic semiconductor chips are singulated into separate optoelectronic semiconductor chips at a later time after a plurality of process steps which take place in the wafer composite.

According to a further embodiment of the method, epitaxial semiconductor columns are epitaxially grown on the growth surface. For example, the epitaxial semiconductor columns have a smaller diameter on the reflector areas than on the LED areas. In particular, the epitaxial semiconductor columns on the reflector areas are epitaxially deposited at the same time as the epitaxial semiconductor columns on the LED areas. The epitaxial semiconductor columns are separated from each other by hollow spaces. For example, the hollow spaces are filled with air and/or a dielectric, preferably completely. In particular, the semiconductor columns and/or the hollow spaces have a main extension direction in a growth direction.

In particular, during the epitaxial growth of the epitaxial semiconductor columns, dislocations that occur near the growth surface in the epitaxial semiconductor columns grow out with advancing epitaxial growth.

According to a further embodiment of the method, the semiconductor columns are epitaxial coalescence to form a closed semiconductor surface. In particular, in this step of the method, the process parameters are changed after the epitaxial growth of the semiconductor columns in such a way that the semiconductor columns grow together and a continuous epitaxially grown semiconductor layer is formed over the epitaxial semiconductor columns.

According to a further embodiment of the method, an active semiconductor layer is epitaxially grown on or over the closed semiconductor surface, wherein the active semiconductor layer is configured to generate electromagnetic radiation. The term “over” means in particular that the two elements thus placed in relation to each other do not necessarily have to be in direct physical contact with each other. Rather, other elements can be arranged in between.

The active semiconductor layer preferably comprises a pn junction, a double heterostructure, a single quantum well or a multiple quantum well structure for the generation of radiation. The term “quantum well structure” does not include here any information about the dimensionality of the quantization. It therefore includes quantum wells, quantum wires and quantum dots and any combination of these structures.

The active semiconductor layer has in particular a nitride compound semiconductor material and is configured to generate electromagnetic radiation from the red spectral range. The closed semiconductor surface, which is formed by the coalescence of the epitaxial semiconductor columns, is configured in particular for the epitaxial growth of an active semiconductor layer of a nitride compound semiconductor material, which generates electromagnetic radiation from the red spectral range during operation. In particular, the active semiconductor layer comprises InGaN or is formed from InGaN.

During the epitaxial deposition of the epitaxial semiconductor columns, the stoichiometric composition of their semiconductor material is changed in particular, so that the lattice constant of the semiconductor material of the epitaxial semiconductor columns changes in the growth direction starting from the growth surface and becomes at least similar to the lattice constant of the active semiconductor layer. Dislocations and/or distortions that occur in the epitaxial semiconductor columns due to the change in the semiconductor material grow out of the epitaxial semiconductor columns laterally, so that a largely defect-free closed semiconductor surface is formed after the coalescence of the epitaxial semiconductor columns.

In this way, optoelectronic semiconductor chips can be generated that are based on a nitride compound semiconductor material and emit red light. Compared to optoelectronic semiconductor chips based on a phosphide compound semiconductor material, these have a lower rate of non-radiative combination in the active semiconductor layer, especially at its interfaces. Phosphide compound semiconductor materials are compound semiconductor materials that contain phosphorus, such as the materials from the system InₓAl_{y}Ga_{1-x-y}P with 0≤x≤1, 0≤y≤1 and x+y≤1.

According to a further embodiment of the method, the active semiconductor layer over the reflector areas is removed, resulting in a plurality of active semiconductor areas over the LED areas. The active semiconductor layer above the reflector areas can be removed by drychemical etching, for example.

In particular, the method of manufacturing a plurality of optoelectronic semiconductor chips comprises the following steps:
-providing the growth surface with a large number of LED areas that are separated from each other by the reflector areas,
epitaxial growing the epitaxial semiconductor columns on the growth surface,
epitaxial coalescence of the semiconductor columns to form the closed semiconductor surface,
epitaxial growth of the active semiconductor layer on or over the closed semiconductor surface, wherein the active semiconductor layer is configured to generate electromagnetic radiation,
removing the active semiconductor layer over the reflector areas such that the plurality of active semiconductor areas is generated over the LED areas.

Preferably, the method steps are carried out in the specified order.

According to a further embodiment of the method, the following steps are carried out during the epitaxial growth of the epitaxial semiconductor columns on or over the growth surface:
applying a structured mask layer on the growth surface, wherein growth areas of the growth surface are exposed,
epitaxial growing the epitaxial semiconductor columns on the growth areas.

In this embodiment of the method, epitaxial growth only takes place on the exposed growth areas of the growth surface, so that the epitaxial semiconductor columns are formed here.

Due to the structured mask layer, it is advantageously possible to deposit epitaxial semiconductor columns, which serve as part of a two-dimensional photonic crystal for the electromagnetic radiation of the active semiconductor areas, simultaneously with the epitaxial semiconductor columns required for the epitaxial deposition of the red light-generating active semiconductor areas based on nitride compound semiconductor materials.

According to a further embodiment of the method, a further closed semiconductor surface remains when removing the active semiconductor layer over the reflector areas. The further closed semiconductor surface does not necessarily have to be the closed semiconductor surface that is formed by the epitaxial coalescence of the epitaxial semiconductor columns. Rather, it can also be a surface that is arranged within the semiconductor material above the epitaxial semiconductor columns.

According to a further embodiment of the method, the epitaxial semiconductor columns form a two-dimensional photonic crystal in the area of the reflector areas for the electromagnetic radiation of the active semiconductor areas. A photonic crystal has a photonic band gap for photons equivalent to the electronic band gap of a semiconductor material. Photons with energies within the photonic band gap cannot propagate in the photonic crystal and are reflected by the photonic crystal. The photonic band gap is formed due to periodic structures of at least two materials that the photonic crystal comprises. The dimension of the photonic crystal is determined by the dimension of the periodicity of the structures. In particular, a photonic crystal has structures in two dimensions that are periodic in two directions in space.

For example, the periodic structure of the two-dimensional photonic crystal is formed by an alternating sequence of epitaxial semiconductor columns and hollow spaces above the reflector area. In particular, the periodicity of the two-dimensional photonic crystal, which corresponds, for example, to the distance between axes of rotation of two directly adjacent epitaxial semiconductor columns, has approximately half the wavelength of the electromagnetic radiation generated by the active semiconductor areas.

According to a further embodiment of the method, the epitaxial semiconductor columns above the reflector areas are exposed when the active semiconductor layer is removed. In other words, in this embodiment of the method, so much semiconductor material is removed above the reflector areas that the hollow spaces between the epitaxial semiconductor columns are freely accessible.

According to a further embodiment of the method, the exposed hollow spaces between the epitaxial semiconductor columns are filled with a dielectric, preferably completely. In particular, a closed surface is created by filling the hollow spaces with the dielectric. The dielectric can be an oxide or a nitride or an organic material, for example. In particular, the epitaxial semiconductor columns and the dielectric in the hollow spaces form a two-dimensional photonic crystal for the electromagnetic radiation of the active semiconductor areas.

According to a further embodiment of the method, when removing the active semiconductor layer over the reflector areas, the epitaxial semiconductor columns over the reflector areas are completely removed, at least against the growth direction, so that cut-outs are formed which are adjacent to the active semiconductor areas.

According to a further embodiment of the method, a reflective layer sequence is applied to the side surfaces of the cut-outs, which reflects electromagnetic radiation from the active semiconductor areas. For example, the reflective layer sequence has dielectric and/or metallic individual layers. For example, the reflective layer sequence is formed from two dielectric layers, between which a metal layer is arranged. For example, the metal layer has one of the following materials or is formed from one of the following materials: gold, silver, aluminum.

According to a further embodiment of the method, a contact layer is deposited over or on the active semiconductor areas, which is configured to inject current into the active semiconductor areas. The contact layer is preferably formed from a metal. A semiconductor contact layer, which comprises a semiconductor material and in particular is doped, can be arranged between the contact layer and the active semiconductor areas.

According to a further embodiment of the method, when removing the active semiconductor layer over the reflector areas, the contact layer is also removed. After removing the contact layer over the reflector areas, for example, an isolation layer is applied over the reflector areas, wherein the isolation layer is laterally directly adjacent to the contact layer.

According to a further embodiment of the method, a mirror layer is applied over the active semiconductor area, which reflects electromagnetic radiation from the active semiconductor areas.

According to a further embodiment of the method, a carrier is attached in a mechanically stable manner over the active semiconductor areas and the growth substrate is subsequently removed. For example, the carrier is attached in a mechanically stable manner by adhesion or soldering. For example, the carrier comprises silicon or is formed from silicon.

With the method the optoelectronic semiconductor chip described below can be manufactured. Features and embodiments described herein in connection with the method may also be embodied in the optoelectronic semiconductor chip and vice versa.

According to an embodiment, the optoelectronic semiconductor chip comprises a hollow space with a bottom surface. The bottom surface is rectangular in plan view, for example. For example, four side surfaces extending in the growth direction are arranged around the bottom surfaces.

According to a further embodiment, the optoelectronic semiconductor chip comprises epitaxial semiconductor columns extending from the bottom surface of the cavity to a radiation exit surface of the optoelectronic semiconductor chip. In particular, the epitaxial semiconductor columns comprise a nitride compound semiconductor material. For example, the epitaxial semiconductor columns in the cavity have a diameter between 100 nanometers and 2 micrometers, inclusive.

According to a further embodiment, the optoelectronic semiconductor chip comprises an active semiconductor area configured to generate electromagnetic radiation. Preferably, the active semiconductor area comprises a nitride compound semiconductor material, for example InGaN, and is configured to generate electromagnetic radiation from the red spectral range.

According to an embodiment of the optoelectronic semiconductor chip, the active semiconductor area is arranged between the bottom surface and the epitaxial semiconductor columns. Particularly preferably, the active semiconductor area is epitaxially grown on end faces of the epitaxial semiconductor columns. For example, the active semiconductor area extends completely along the bottom surface of the cavity. Alternatively, it is also possible for the active semiconductor area to be interrupted by intermediate regions.

According to a further embodiment, the optoelectronic semiconductor chip comprises a reflector, which is arranged on side surfaces of the cavity and reflects electromagnetic radiation from the active semiconductor area. Preferably, the reflector is arranged completely circumferentially around the active semiconductor area. For example, the reflector forms the side surfaces of the cavity.

According to a further embodiment, the optoelectronic semiconductor chip comprises the cavity including the bottom surface, the epitaxial semiconductor columns extending from the bottom surface of the cavity to the radiation exit surface of the optoelectronic semiconductor chip, the active semiconductor area is configured to generate the electromagnetic radiation and the reflector arranged on the side surfaces of the cavity and reflecting the electromagnetic radiation of the active semiconductor area, wherein the active semiconductor area is arranged between the bottom surface and the epitaxial semiconductor columns.

According to a further embodiment of the optoelectronic semiconductor chip, hollow spaces are arranged between the epitaxial semiconductor columns in the cavity. For example, the hollow spaces are filled with air. By structuring the cavity with the epitaxial semiconductor columns and the hollow spaces, the efficiency of the optoelectronic semiconductor chip is increased in particular, since electromagnetic radiation that is reflected from the reflector on the side surfaces into the cavity is scattered. In particular, the epitaxial semiconductor columns in the cavity are not part of a photonic crystal for electromagnetic radiation of the active semiconductor area.

According to a further embodiment of the optoelectronic semiconductor chip, the reflector comprises epitaxial semiconductor columns that are part of a two-dimensional photonic crystal for the electromagnetic radiation of the active semiconductor area. For example, the epitaxial semiconductor columns in the cavity of the semiconductor chip have a larger diameter than the epitaxial semiconductor columns comprised by the reflector. In particular, the epitaxial semiconductor columns of the reflector extend parallel to the epitaxial semiconductor columns in the cavity.

According to a further embodiment of the optoelectronic semiconductor chip, the epitaxial semiconductor columns in the cavity have a different diameter than the epitaxial semiconductor columns comprised by the reflector. For example, the epitaxial semiconductor columns in the cavity have a larger diameter than the epitaxial semiconductor columns of the reflector. For example, the epitaxial semiconductor columns of the reflector have a diameter between 100 nanometers and 500 nanometers inclusive, while the epitaxial semiconductor columns in the cavity may have a diameter of up to 2 micrometers.

According to a further embodiment of the optoelectronic semiconductor chip, hollow spaces are formed between the epitaxial semiconductor columns of the reflector. The hollow spaces are filled with a dielectric, for example.

Furthermore, it is also possible that the reflector has a reflective layer sequence or is formed from a reflective layer sequence that is arranged on the side surfaces of the cavity or forms the side surfaces of the cavity.

According to a further embodiment of the optoelectronic semiconductor chip, an angle filter is applied to the radiation exit surface. The angle filter reflects electromagnetic radiation of the active semiconductor area that impinges on the angle filter at an angle greater than or equal to a boundary angle, while electromagnetic radiation that impinges on the angle filter at an angle less than or equal to the boundary angle is transmitted. The angle is included here with a surface normal of the radiation exit surface. For example, the boundary angle has a value of at most 30° or at most 45°.

Electromagnetic radiation that hits the angle filter and is reflected back into the cavity is scattered by the structures in the cavity, such as the epitaxial semiconductor columns and the hollow spaces, as well as the mirror layer sequence and the mirror layer, and is thus recycled.

The angle filter can be, for example, a prism foil, a single prism, a Bragg reflector and/or another photonic crystal. The angle filter can be used to increase the directionality of the electromagnetic radiation emitted by the optoelectronic semiconductor chip. A light spot emitted by the optoelectronic semiconductor chip can also be reduced in size and delimited more sharply by the angle filter.

According to a further embodiment of the optoelectronic semiconductor chip, the active semiconductor area comprises a nitride compound semiconductor material or consists of a nitride compound semiconductor material. Furthermore, the active semiconductor area is preferably configured to generate electromagnetic radiation from the red spectral range.

According to a further embodiment, the optoelectronic semiconductor chip has an edge length of at most 10 micrometers, at most 5 micrometers or at most 2 micrometers. For example, the optoelectronic semiconductor chip has an edge length of between 2 micrometers and 4 micrometers inclusive. Especially for optoelectronic semiconductor chips with small edge lengths, the use of a cavity and measures to increase efficiency and directionality, as proposed herein, is advantageous to achieve an efficient optoelectronic semiconductor chip.

The optoelectronic semiconductor chip can be used in a display, for example for applications in the field of virtual and/or artificial reality. For example, the optoelectronic semiconductor chip forms a red emitting pixel of the display. The reflector, which is designed as a two-dimensional photonic crystal, for example, suppresses crosstalk to a directly adjacent pixel with advantage.

According to a further embodiment, the optoelectronic semiconductor chip is designed as a micro-LED. A micro-LED is, for example, any light-emitting diode (abbreviated to “LED”) with particularly small dimensions. In general, a micro-LED is not a laser that generates electromagnetic laser radiation through stimulated emission.

As a rule—and in addition to size, this is also a very important criterion—the growth substrate is removed from micro-LEDs, so that typical thicknesses of such micro-LEDs are in the range from 1.5 micrometers up to and including 10 micrometers, for example.

In principle, a micro-LED does not necessarily have to have a rectangular radiation exit surface. For example, a micro-LED has a radiation exit surface in which, in plan view on the active semiconductor area, each lateral extension of the radiation exit surface is less than or equal to 100 micrometers or less than or equal to 70 micrometers.

For example, an edge length of less than or equal to 70 micrometers or less than or equal to 50 micrometers is often mentioned as a criterion for rectangular micro-LEDs, particularly in plan view on the active semiconductor area.

In most cases, such micro-LEDs are provided on wafers with detachable holding structures that are non-destructive for the micro-LED.

Micro-LEDs are currently mainly used in displays. Thereby the micro-LEDs form pixels or sub-pixels and emit light of a defined color. Due to the small pixel size and high density with a small distance, micro-LEDs are suitable among other things for small monolithic displays for AR applications, in particular data glasses. Work is also underway on other applications, particularly the application in data communication and pixelated lighting applications.

Various spellings for “micro-LED” can be found in the literature, e.g. μLED, μ-LED, uLED, u-LED or Micro Light Emitting Diode.

### BRIEF DESCRIPTION OF THE DRAWINGS

Further advantageous embodiments and implementations of the optoelectronic semiconductor chip and of the method for its manufacture are shown in the exemplary embodiment described below in conjunction with the figures.

FIGS. 1 to 9 schematically show different stages of a method for manufacturing a plurality of optoelectronic semiconductor chips according to an exemplary embodiment;

FIGS. 10 and 11 show schematic sectional views of optoelectronic semiconductor chips according to two exemplary embodiments;

FIGS. 12 and 13 schematically show stages of a method according to a further exemplary embodiment;

FIG. 14 shows a schematic sectional view of an optoelectronic semiconductor chip according to a further exemplary embodiment;

FIGS. 15 and 16 schematically show stages of a method according to a further exemplary embodiment; and

FIG. 17 shows a schematic sectional view of an optoelectronic semiconductor chip according to a further exemplary embodiment.

Elements that are identical, similar or have the same effect are marked with the same reference symbols in the figures. The figures and the proportions of the elements shown in the figures should not be considered to be to scale. Rather, individual elements, in particular layer thicknesses, may be shown in exaggerated size for better visualization and/or understanding.

### DETAILED DESCRIPTION OF ILLUSTRATIVE EMBODIMENTS

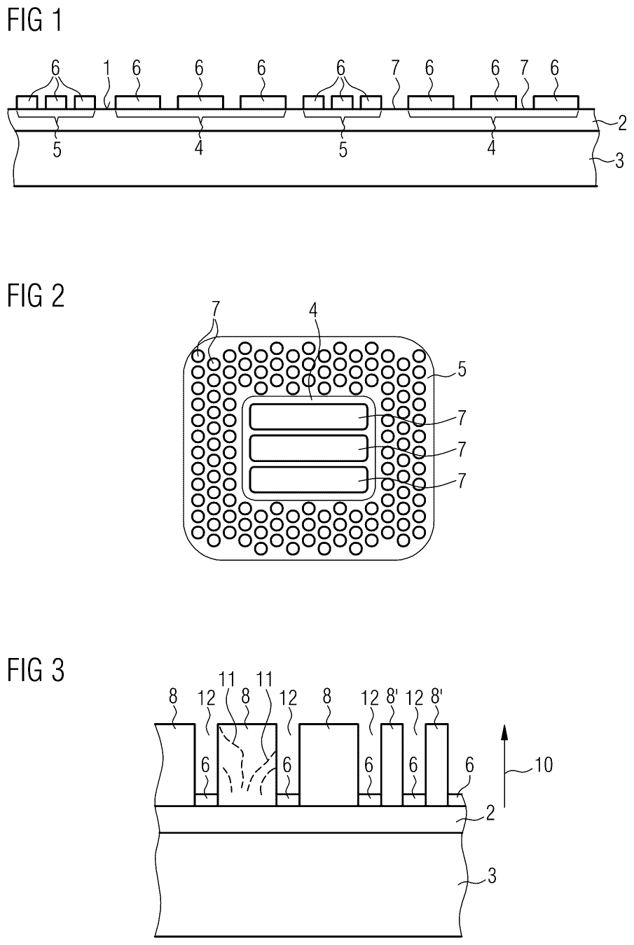

In the method according to the exemplary embodiment of FIGS. 1 to 9, a growth surface 1 is first provided. In the present case, the growth surface 1 is formed by a main surface of an n-doped epitaxial semiconductor growth layer 2 which is applied to a growth substrate 3. The growth substrate 3 comprises, for example, one of the following materials or is formed from one of the following materials: sapphire, silicon. All semiconductor materials deposited in the present method are selected from the system of nitride compound semiconductor materials.

In the present case, the growth surface 1 has LED areas 4 and reflector areas 5, whereby the LED areas 4 are separated from each other by the reflector areas 5. In particular, the growth surface 1 is provided as part of a wafer on which a plurality of LED areas 4 and reflector areas 5 are arranged.

A structured mask layer 6 is applied to the growth surface 1, wherein growth areas 7 of the growth surface 1 are exposed (FIG. 1). The growth areas 7 are configured for the epitaxial deposition of nitride compound semiconductor materials.

In FIG. 1, only two LED areas 4 and two reflector areas 5 are shown by way of example. As a rule, however, the growth surface 1 has more than two LED areas 4 and two reflector areas 5.

FIG. 2 shows an exemplary plan view of an LED area 4 and a reflector area 5. The LED area 4 is completely surrounded by the reflector area 5. In the present case, the LED area 4 has three growth areas 7 with a rectangular shape in plan view, which are configured for the epitaxial deposition of epitaxial semiconductor columns 8, which are arranged in a cavity 27 in the finished optoelectronic semiconductor chip.

For reasons of clarity, only one LED area 4 with a directly adjacent reflector area 5 is often shown in the figures below. However, the method steps described below in conjunction with the figures are carried out in parallel over the entire wafer.

Epitaxial semiconductor columns 8, 8′ are epitaxially deposited on the growth areas 7 of the growth surface in a growth direction 10 (FIG. 3). The epitaxial semiconductor columns 8, 8′ are n-doped in the present case. The stoichiometry of the semiconductor material of the epitaxial semiconductor columns 8, 8′ is changed during growth. Dislocations 11, which arise during epitaxial deposition due to the changing lattice constant, grow laterally out of the epitaxial semiconductor columns 8, 8′. Hollow spaces 12 arise thereby above the material of the structured mask layer 6, as no epitaxial growth of the nitride compound semiconductor material takes place on the structured mask layer 6.

The dimensions and geometries of the epitaxial semiconductor columns 8, 8′ are determined by the dimensions and geometries of the growth areas 7. On the reflector area 5, epitaxial semiconductor columns 8′ are grown, which have a smaller diameter than the epitaxial semiconductor columns 8 that are deposited on the LED area 4.

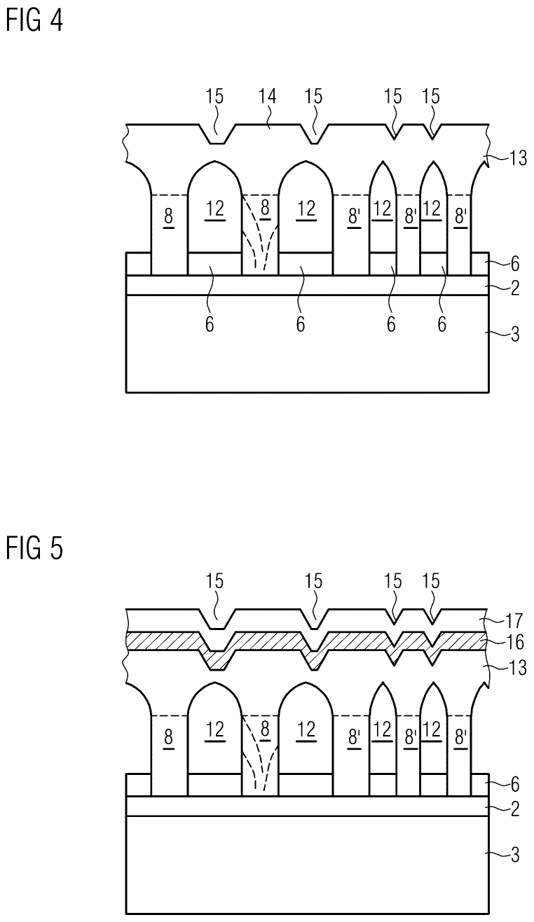

Then, the growth parameters during deposition of the nitride compound semiconductor material are changed such that the deposited nitride compound semiconductor material coalesce and forms a fully continuous and closed semiconductor layer 13 over the epitaxial semiconductor columns 8, 8′ and the hollow spaces 12. In particular, one surface of the closed semiconductor layer forms a closed semiconductor surface 14 with indentations 15 over the hollow spaces 12 (FIG. 4).

An active semiconductor layer 16 is epitaxially deposited on the closed semiconductor surface 14. The active semiconductor layer 16 is configured to generate electromagnetic radiation from the red spectral range. For example, the electromagnetic radiation generated in the active semiconductor layer 16 has a wavelength of approximately 620 nanometers.

On the active semiconductor layer 16, a semiconductor contact layer 17 is deposited, which is also based on a nitride compound semiconductor material and is p-doped (FIG. 5). The indentations 15 in the closed semiconductor surface 14 continue in the active semiconductor layer 16 and in the semiconductor contact layer 17.

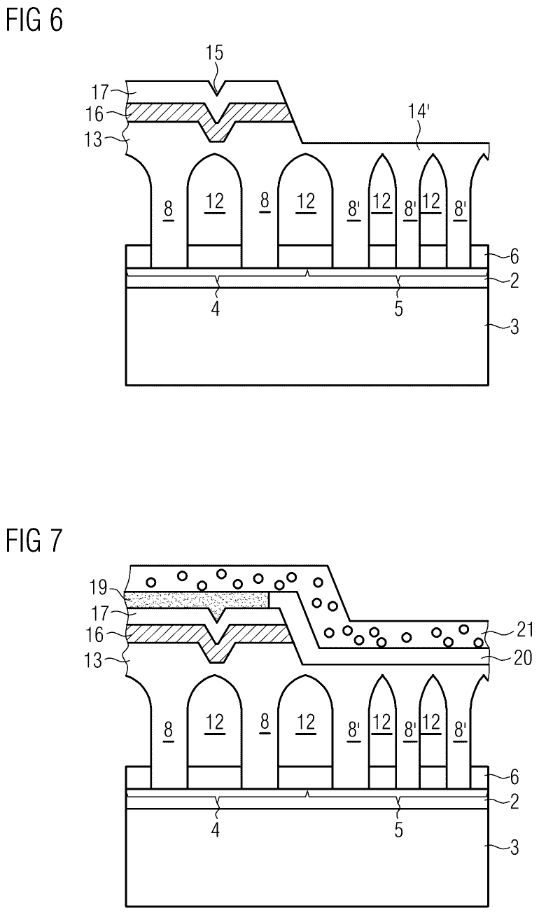

In a further step, the active semiconductor layer 16 and the semiconductor contact layer 17 over the reflector areas 5 are removed by etching, so that active semiconductor areas 18 are formed. A closed semiconductor surface 14′ remains thereby above the hollow spaces 12 between the epitaxial semiconductor columns 8′ on the reflector area 5 (FIG. 6).

A metallic contact layer 19 is then applied to the semiconductor contact layer 17 over the LED areas 4, for example by sputtering. An isolation layer 20 which is directly adjacent to the contact layer 19 is applied over the reflector areas 5. The isolation layer 20 is formed from a dielectric, for example.

Furthermore, over the entire surface of the resulting semiconductor chip composite, a mirror layer 21 is applied, which is configured to reflect electromagnetic radiation generated in the active semiconductor area 18 (FIG. 7). The mirror layer 21 has, for example, a metal or is formed from a metal.

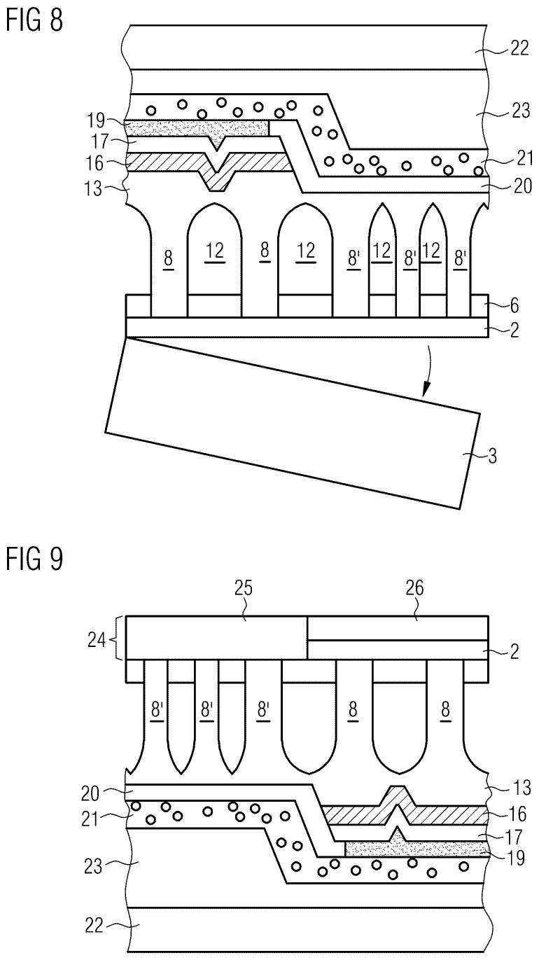

A carrier 22 is then applied to the resulting semiconductor chip composite, for example with a solder 23 or an adhesive, and the growth substrate 3 is subsequently removed (FIG. 8). The carrier 22 comprises silicon in the present case.

In a further step, n-contacts 24 are provided on a main surface of the semiconductor chip composite facing away from the carrier 22 (FIG. 9). The n-contact 24 has metallic areas 25 above the reflector areas 5 and transparent areas 26 above the LED areas 4. For example, the n-contact above the LED areas comprises a transparent conductive oxide or is formed from a transparent conductive oxide.

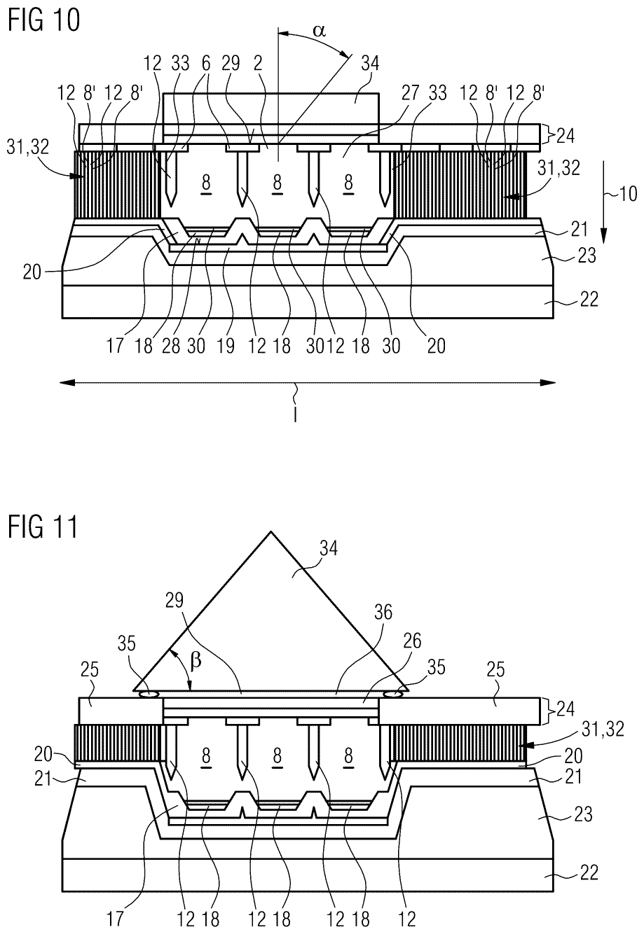

The optoelectronic semiconductor chip according to the exemplary embodiment of FIG. 10 can, for example, be generated using the method as described in connection with FIGS. 1 to 9.

The optoelectronic semiconductor chip according to the exemplary embodiment of FIG. 10 has a cavity 27 with a bottom surface 28. In the present case, epitaxial semiconductor columns 8 which are separated from each other by hollow spaces 12 filled with air extend from the bottom surface 28 to a radiation exit surface 29.

Furthermore, the optoelectronic semiconductor chip comprises an active semiconductor area 18 arranged at end faces 30 of the epitaxial semiconductor columns 8 in the cavity 27. In particular, the active semiconductor area 18 is epitaxially grown on the end face 30. In the present case, the active semiconductor area 18 is formed from InGaN and is configured to generate electromagnetic radiation from the red spectral range with a wavelength of approximately 620 nanometers.

The optoelectronic semiconductor chip further comprises epitaxial semiconductor columns 8′, which are separated from each other by air-filled hollow spaces 12 and form a two-dimensional photonic crystal 31 as a reflector 32 for the electromagnetic radiation of the active semiconductor area 18. In the present case, the two-dimensional photonic crystal 31 is arranged on side surfaces 33 of the cavity 27 and completely surrounds the active semiconductor area 18. For example, the two-dimensional photonic crystal 31 has a periodicity between 150 nanometers and 200 nanometers inclusive. An effective refractive index of the two-dimensional photonic crystal 31 is, for example, between 1.6 and 2.2, inclusive.

A p-doped semiconductor contact layer 17 is also applied to the active semiconductor area 18, which is also grown epitaxially. A metallic contact layer 19 is also applied to the semiconductor contact layer 17. The semiconductor contact layer 17 and the metallic contact layer 19 form a p-contact.

Furthermore, the optoelectronic semiconductor chip comprises a carrier 22 made of silicon, which is attached to the epitaxial structure comprising the active semiconductor area 18 and the two-dimensional photonic crystal 31 by means of a metal solder 23.

Furthermore, the optoelectronic semiconductor chip comprises a mirror layer 21 which is arranged continuously between the epitaxial structure and the carrier 22. The mirror layer 21 reflects electromagnetic radiation from the active semiconductor area 18.

Furthermore, the optoelectronic semiconductor chip according to FIG. 10 comprises an isolation layer 20 which electrically insulates the mirror layer 21 from the p-contact.

Finally, the optoelectronic semiconductor chip as shown in FIG. 10 comprises an n-contact 24, which is metallic on the two-dimensional photonic crystal 31 and transparent on the radiation exit surface 29.

An angle filter 34 is applied to the radiation exit surface 29. The angle filter 34 is, for example, a Bragg reflector. The angle filter 34 has a significantly higher transmission, in particular for electromagnetic radiation of the active semiconductor area 18 that is incident at an angle that is smaller than a boundary angle α of 30°, than for angles of incidence greater than the boundary angle α. In this way, the directionality of the light emitted by the optoelectronic semiconductor chip can be increased.

The optoelectronic semiconductor chip according to the exemplary embodiment of FIG. 10 has a small edge length 1, for example of at most 10 micrometers. In particular, the hollow spaces 12 between the epitaxial semiconductor columns 8 in the cavity 27 and edge diffraction effects due to the small dimension of the optoelectronic semiconductor chip lead to light scattering within the cavity 27, which allows photon recycling for electromagnetic radiation reflected back from the angle filter 34.

The optoelectronic semiconductor chip according to the exemplary embodiment of FIG. 11 is designed, for example, like the optoelectronic semiconductor chip according to the exemplary embodiment of FIG. 10 except for the angle filter 34.

The angle filter 34 of the optoelectronic semiconductor chip according to the exemplary embodiment of FIG. 11 is formed in the present case as a prism, which is arranged on the radiation exit surface 29 of the optoelectronic semiconductor chip. In particular, the angle filter 34 is attached to the metallic area 25 of the n-contact 24 above the two-dimensional photonic crystal 31 using an adhesive 35.

A layer 36 with a low refractive index, which is in particular smaller than the refractive index of the angle filter 34 and/or smaller than the refractive index of the transparent area 26 of the n-contact 24, is further arranged between the angle filter 34 and the transparent area 26 of the n-contact 24. Furthermore, an angle of inclination β of the prism has a value of approximately 45°. It is also possible that several contiguous prisms, such as a prism foil, are used as the angle filter 34. Furthermore, the prism may have a highly refractive glass or consist of a highly refractive glass.

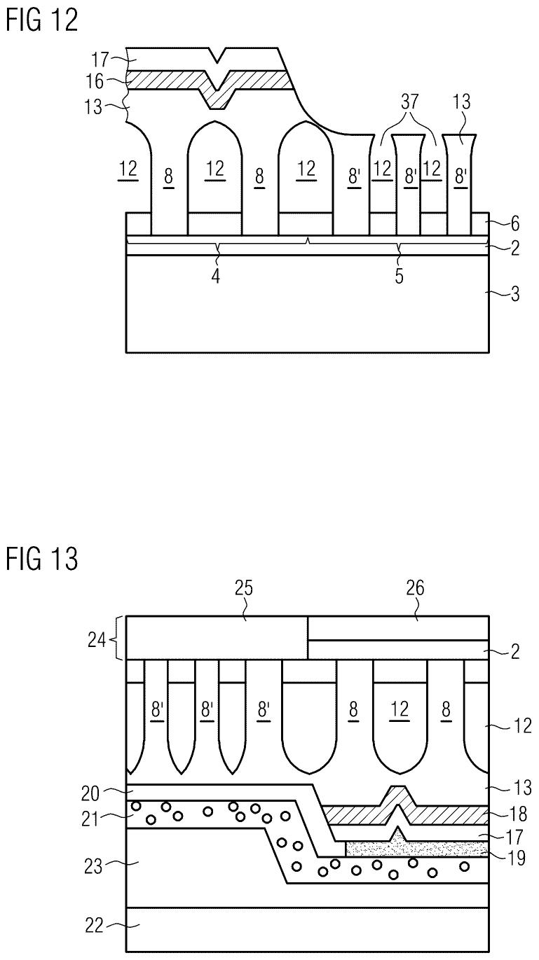

In the method according to the exemplary embodiment of FIGS. 12 and 13, the steps are first carried out as already described with reference to FIGS. 1 to 5.

In a further step, the semiconductor material above the reflector area 5 is removed so that the epitaxial semiconductor columns 8′ and the hollow spaces 12 are exposed (FIG. 12). In the next step, the hollow spaces 12 are filled with a dielectric 37. Then n-contacts 24 are applied (FIG. 13), as already described in connection with FIG. 9.

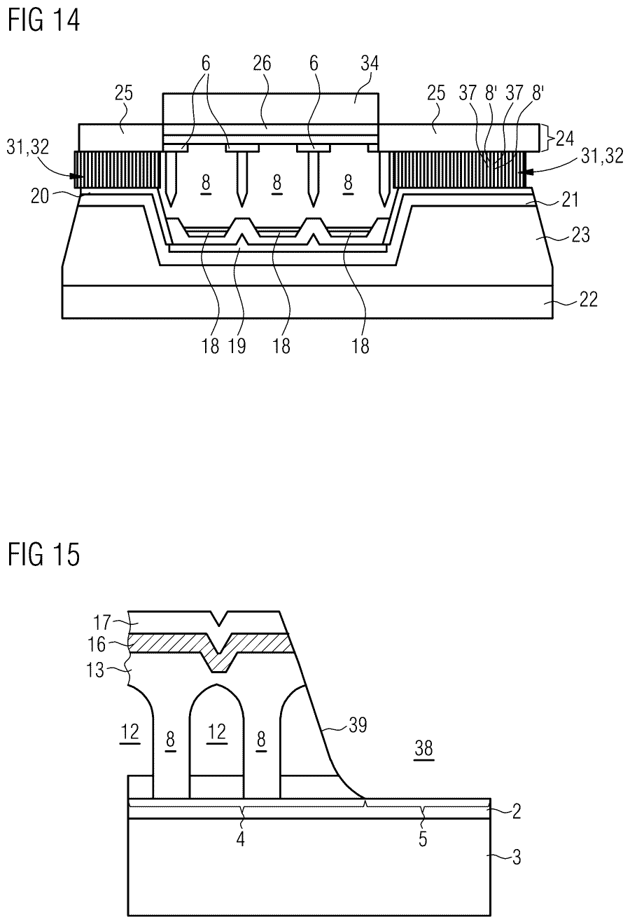

The optoelectronic semiconductor chip according to the exemplary embodiment of FIG. 14 can be manufactured, for example, using the method as described with reference to FIGS. 12 and 13. In particular, the optoelectronic semiconductor chip according to the exemplary embodiment of FIG. 14 has no semiconductor material of the continuous closed semiconductor layer 13 over the reflector area 5, which was formed during epitaxial growth over the epitaxial semiconductor columns 8′ in the reflector area 5. In addition, the hollow spaces 12 of the two-dimensional photonic crystal 31 are filled with a dielectric 37. In addition, mask layer 6 and the semiconductor material grown between the mask layer 6 have also been removed before the n-contact 24 is applied.

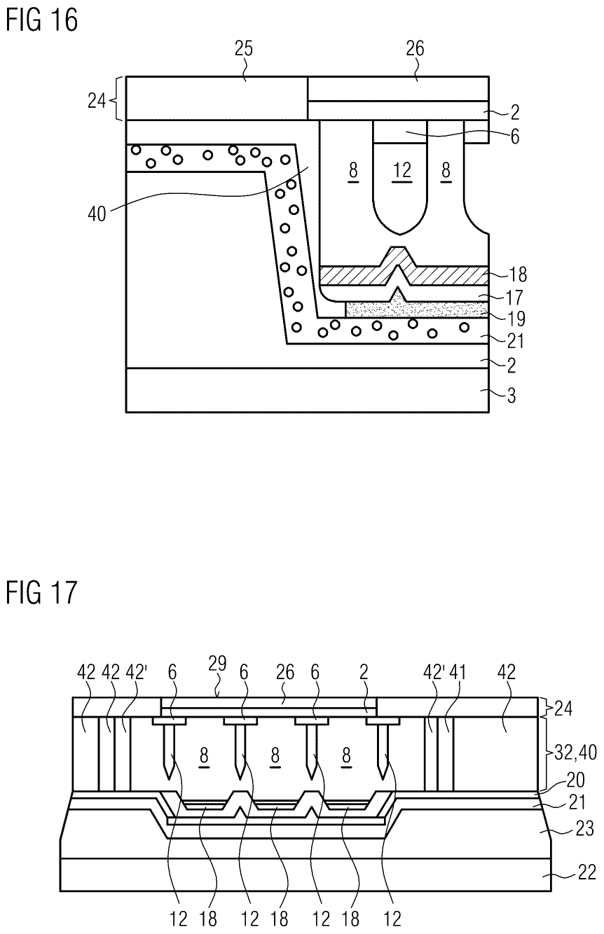

Also in the method according to the exemplary embodiment of FIGS. 15 and 16, the steps already described with reference to FIGS. 1 to 5 are carried out first.

In a further step, the semiconductor material above the reflector areas 5 is removed, for example by etching. In contrast to the method step as described with reference to FIG. 6, however, the entire semiconductor material above the reflector areas 5 is removed here. In particular, the epitaxial semiconductor columns 8′ and the hollow spaces 12 above the reflector areas 5 are removed (FIG. 15). This creates cut-outs 38 adjacent to the active semiconductor areas 18. The cut-outs 38 have a depth of a few micrometers, for example (FIG. 15).

A reflective layer sequence 40 is then arranged on the side surfaces 39 of the cut-outs 38 (FIG. 16). The reflective layer sequence 40 has a metallic single layer 41, which is arranged between two dielectric single layers 42, 42′. Then n-contacts 24 are applied, as already described in connection with FIG. 9.

The optoelectronic semiconductor chip according to the exemplary embodiment of FIG. 17 can, for example, be generated using the method as described with reference to FIGS. 15 and 16. In the optoelectronic semiconductor chip according to FIG. 17, the reflector 32, which is arranged on side surfaces 33 of the cavity 27, is formed by a reflective layer sequence 40 dielectric/metal/dielectric. Furthermore, an isolation layer 20 is arranged between the reflective layer sequence 20 and the p-contact to prevent a short circuit.

The invention is not limited to the exemplary embodiment by the description based on these. Rather, the invention includes any new feature as well as any combination of features, which includes in particular any combination of features in the patent claims, even if this feature or combination itself is not explicitly stated in the patent claims or embodiments.

1-17. (canceled)

18. A method for manufacturing a plurality of optoelectronic semiconductor chips, the method comprising:
providing a growth surface with a plurality of LED areas, which are separated from each other by reflector areas;
epitaxial growing epitaxial semiconductor columns on the growth surface;
epitaxial coalescing the epitaxial semiconductor columns so that a closed semiconductor surface is formed;
epitaxial growing an active semiconductor layer on or over the closed semiconductor surface, wherein the active semiconductor layer is configured to generate electromagnetic radiation; and
removing the active semiconductor layer over the reflector areas such that a plurality of active semiconductor areas is generated over the LED areas.

19. The method according to the claim 18, wherein removing the active semiconductor layer over the reflector areas comprises retaining a further closed semiconductor surface.

20. The method according to claim 18, wherein the epitaxial semiconductor columns form a two-dimensional photonic crystal for the electromagnetic radiation of the active semiconductor areas over the reflector areas.

21. The method according to claim 18, wherein the epitaxial semiconductor columns on the reflector areas are exposed when the active semiconductor layer over the reflector areas is removed.

22. The method according to the claim 21, further comprising filling hollow spaces between the epitaxial semiconductor columns with a dielectric.

23. The method according to claim 22, wherein the epitaxial semiconductor columns and the dielectric form a two-dimensional photonic crystal for the electromagnetic radiation of the active semiconductor areas.

24. The method according to claim 18, wherein removing the active semiconductor layer over the reflector areas comprises completely removing the epitaxial semiconductor columns over the reflector areas at least against a growth direction so that cut-outs are formed, which are adjacent to the active semiconductor areas.

25. The method according to claim 24, further comprising applying a reflective layer sequence reflecting the electromagnetic radiation of the active semiconductor areas to side surfaces of the cut-outs.

26. An optoelectronic semiconductor chip comprising:
a cavity comprising a bottom surface;
epitaxial semiconductor columns, which extend from the bottom surface of the cavity to a radiation exit surface of the optoelectronic semiconductor chip;
an active semiconductor area configured to generate electromagnetic radiation; and
a reflector arranged at side surfaces of the cavity and configured to reflect the electromagnetic radiation,
wherein the active semiconductor area is arranged between the bottom surface and the epitaxial semiconductor columns.

27. The optoelectronic semiconductor chip according claim 26, wherein hollow spaces are arranged between the epitaxial semiconductor columns.

28. The optoelectronic semiconductor chip according to claim 27, wherein the reflector comprises the epitaxial semiconductor columns, which are part of a two-dimensional photonic crystal for the electromagnetic radiation.

29. The optoelectronic semiconductor chip according to claim 28, wherein the hollow spaces are arranged between the epitaxial semiconductor columns of the reflector.

30. The optoelectronic semiconductor chip according to claim 26, wherein the reflector comprises a reflective layer sequence.

31. The optoelectronic semiconductor chip according to claim 26, wherein on the radiation exit surface an angle filter is arranged, which is configured to reflect the electromagnetic radiation that impinges on the angle filter at a predetermined angle.

32. The optoelectronic semiconductor chip according to claim 26, wherein the active semiconductor area comprises a nitride compound semiconductor material and is configured to generate the electromagnetic radiation of a red spectral range.

33. The optoelectronic semiconductor chip according to claim 26, wherein the optoelectronic semiconductor chip has an edge length of at most 10 micrometers.

34. The optoelectronic semiconductor chip according to claim 26, wherein the optoelectronic semiconductor chip is a micro-LED.
